(19) United States
(12) Patent Application Publication
(10) Pub. No.: US 2025/0334624 A1
(43) Pub. Date: Oct. 30, 2025

(54) ELECTROMAGNETIC INTERFERENCE TESTING SYSTEM AND METHOD FOR ELECTRIC AUTOMOBILE UNDER DYNAMIC WORKING CONDITIONS

(71) Applicant: Guangdong Polytechnic Normal University, Guangzhou (CN)

(72) Inventors: Senming Zhong, Guangzhou (CN); Xiaojun Wang, Guangzhou (CN); Jian Ouyang, Guangzhou (CN); Yingjie Liu, Guangzhou (CN); Zhangjun Wu, Guangzhou (CN)

(21) Appl. No.: 18/799,961

(22) Filed: Aug. 9, 2024

(30) Foreign Application Priority Data
Apr. 28, 2024 (CN) 202410517006.X

(51) Int. Cl. G01R 31/00; B60L 3/12

(52) U.S. Cl. CPC G01R 31/001; B60L 3/12; G01R 31/006

(57) ABSTRACT

The present disclosure provides an electromagnetic interference testing system and method for an electric automobile under dynamic working conditions. The method includes the steps of: estimating electromagnetic interference presence state information about each of all wiring harnesses connected to a motor driving device based on operation state data, and identifying an abnormal wiring harness in which a signal conduction interference event occurs; tracking and identifying an electromagnetic interference signal of the abnormal wiring harness to obtain propagation path information, and determining, based on this, an electronic device which may be affected by the electromagnetic interference signal inside the electric automobile; and determining whether an operation disorder event occurs in the electronic device, and determining an electromagnetic interference concentrated circuit interval inside the electronic device, which is convenient for subsequent electromagnetic interference shielding processing for corresponding circuit intervals.

### CROSS-REFERENCE TO RELATED APPLICATIONS

This application claims priority of Chinese Patent Application No. 202410517006.X, filed on Apr. 28, 2024, the entire contents of which are incorporated herein by reference.

### TECHNICAL FIELD

The present disclosure relates to the field of electric automobiles, and more particularly, to an electromagnetic interference testing system and method for an electric automobile under dynamic working conditions.

### BACKGROUND

As a highly integrated electromechanical device, an electric automobile includes different types of electronic devices such as power source electromagnetism, a motor driver and a central control server. The motor driver obtains electric energy from the power source electromagnetism and generates a large number of high-frequency electromagnetic wave signals during operation, and these high-frequency electromagnetic wave signals are transmitted to other electronic devices along different wiring harnesses under a controller area network (CAN) bus inside the motor, thus causing interference to other electronic devices. The high-frequency electromagnetic wave signals of the electric automobile cannot be completely eliminated. In order to ensure that electronic devices of the electric automobile can maintain normal operation under a high-frequency electromagnetic wave environment, it is necessary to accurately identify the transmission of high-frequency electromagnetic waves inside the electric automobile. However, the high-frequency electromagnetic waves inside the electric automobile are complex and variable, so it is impossible to track the high-frequency electromagnetic waves continuously and accurately, reducing the reliability of shielding the high-frequency electromagnetic waves.

### SUMMARY

An object of the present disclosure is to provide an electromagnetic interference testing system and method for an electric automobile under dynamic working conditions. Based on operation state data of a motor driving device of an electric automobile under a driving condition, electromagnetic interference presence state information about each of all wiring harnesses connected to the motor driving device is estimated to identify an abnormal wiring harness in which a signal conduction interference event occurs, which can accurately identify the propagation of electromagnetic interference inside the electric automobile; an electromagnetic interference signal of the abnormal wiring harness is tracked and identified to obtain propagation path information about the electromagnetic interference signal, to determine an electronic device which may be affected by the electromagnetic interference signal inside the electric automobile, which is convenient for subsequent separate electromagnetic interference identification of a corresponding electronic device; and it is determined whether an operation disorder event occurs in the electronic device based on an operating record of the electronic device, and an electromagnetic interference concentrated circuit interval inside the electronic device is determined based on electromagnetic signal change data inside the electronic device, which facilitates the subsequent electromagnetic interference shielding treatment for a corresponding circuit interval, improves the accuracy of battery interference identification of the electric automobile, and ensures the working reliability of the electric automobile.

The present disclosure is realized by the following technical solutions.

An electromagnetic interference testing system for an electric automobile under dynamic working conditions includes:
an electromagnetic interference presence identification module, configured to acquire operation state data of a motor driving device of an electric automobile under a driving condition, and estimate electromagnetic interference presence state information about each of all wiring harnesses connected to the motor driving device based on the operation state data,
an abnormal wiring harness identification module, configured to identify an abnormal wiring harness in which a signal conduction interference event occurs based on the electromagnetic interference presence state information,
an electromagnetic interference propagation path determination module, configured to track and identify an electromagnetic interference signal of the abnormal wiring harness to obtain propagation path information about the electromagnetic interference signal,
an electronic device identification module, configured to determine an electronic device which may be affected by the electromagnetic interference signal inside the electric automobile based on the propagation path information, and perform positioning identification on the electronic device,
an electronic device operation determination module, configured to determine whether an operation disorder event occurs in the electronic device based on an operating record of the electronic device, and
an electromagnetic interference circuit interval determination module, configured to determine an electromagnetic interference concentrated circuit interval inside the electronic device based on electromagnetic signal change data inside the electronic device when an operation disorder event occurs in the electronic device.

Alternatively, the electromagnetic interference presence identification module being configured to acquire operation state data of a motor driving device of an electric automobile under a driving condition, and estimate electromagnetic interference presence state information about each of all wiring harnesses connected to the motor driving device based on the operation state data includes:
acquiring reference operating current data of the motor driving device of the electric automobile under a reference driving condition, and analyzing the reference operating current data to obtain working current data of each of the all wiring harnesses connected to the motor driving device; and obtaining an effective working current data change model of the harness itself when a preset regular driving condition change of the electric automobile occurs based on the working current data; and
acquiring actual operating current data of the motor driving device when the preset regular driving condition change of the electric automobile occurs, and analyzing the actual operating current data to obtain actual working current data of each of the all wiring harnesses; and comparing actual working current data of the wiring harness with predicted working current data estimated by a corresponding effective working current data change model, and determining electromagnetic interference intensity and frequency state information existing inside the wiring harness itself when the preset regular driving condition change occurs; and the an abnormal wiring harness identification module being configured to identify an abnormal wiring harness in which a signal conduction interference event occurs based on the electromagnetic interference presence state information includes:
obtaining an electromagnetic interference average intensity value and an electromagnetic interference peak frequency value inside the wiring harness itself based on the electromagnetic interference intensity and frequency state information, when the electromagnetic interference average intensity value is greater than a preset intensity threshold value or the electromagnetic interference peak frequency value is greater than a preset frequency threshold value, a corresponding wiring harness being determined as an abnormal wiring harness in which a signal conduction interference event occurs; otherwise, a corresponding wiring harness being not determined as an abnormal wiring harness in which a signal conduction interference event occurs.

Alternatively, the electromagnetic interference propagation path determination module being configured to track and identify an electromagnetic interference signal of the abnormal wiring harness to obtain propagation path information about the electromagnetic interference signal includes:
performing signal sampling and identification on all signal transmission channels correspondingly connected to the abnormal wiring harness to obtain signal frequency domain information transmitted in real-time by the signal transmission channels; comparing the signal frequency domain information with frequency domain distribution feature information about an electromagnetic interference signal existing inside the abnormal wiring harness itself, if the signal frequency domain information matches the frequency domain distribution feature information, it being determined that the electromagnetic interference signal exists inside the signal transmission channel; and obtaining propagation path information about electromagnetic interference signals on the basis of all the signal transmission channels in which electromagnetic interference signals exist; and
the electronic device identification module being configured to determine an electronic device which may be affected by the electromagnetic interference signal inside the electric automobile based on the propagation path information, and perform positioning identification on the electronic device includes:
determining all electronic devices capable of receiving the electromagnetic interference signal based on the propagation path information; and determining an intensity ratio of the electromagnetic interference signal in a real-time working current signal based on an actual working current signal of the electronic device, if the intensity ratio is greater than or equal to a preset ratio threshold value, it being determined that the electronic device may be affected by the electromagnetic interference signal, and it being determined that position information about the electronic device which may be affected by the electromagnetic interference signal in a global signal flow map of the electric automobile, as a result of the positioning identification.

Alternatively, the electronic device operation determination module being configured to determine whether an operation disorder event occurs in the electronic device based on an operating record of the electronic device includes:
acquiring an operating record of the electronic device which may be affected by the electromagnetic interference signal based on the result of the positioning identification, and analyzing the operating record to obtain a processing time consumption of a received signal by the electronic device, if the processing time consumption is greater than a preset time threshold value, it being determined that an operation disorder event occurs in the electronic device; otherwise, it being determined that no operation disorder event occurs in the electronic device; and
the electromagnetic interference circuit interval determination module being configured to determine an electromagnetic interference concentrated circuit interval inside the electronic device based on electromagnetic signal change data inside the electronic device when an operation disorder event occurs in the electronic device includes:
analyzing electromagnetic signal change data inside the electronic device when an operation disorder event occurs in the electronic device to obtain a high-frequency electromagnetic signal aggregate circuit part inside the electronic device, as an electromagnetic interference concentrated circuit interval inside the electronic device.

An electromagnetic interference testing method for an electric automobile under dynamic working conditions includes:
acquiring operation state data of a motor driving device of an electric automobile under a driving condition, and estimating electromagnetic interference presence state information about each of all wiring harnesses connected to the motor driving device based on the operation state data; and identifying an abnormal wiring harness in which a signal conduction interference event occurs based on the electromagnetic interference presence state information;
tracking and identifying an electromagnetic interference signal of the abnormal wiring harness to obtain propagation path information about the electromagnetic interference signal; and determining an electronic device which may be affected by the electromagnetic interference signal inside the electric automobile based on the propagation path information, and performing positioning identification on the electronic device; and
determining whether an operation disorder event occurs in the electronic device based on an operating record of the electronic device; and determining an electromagnetic interference concentrated circuit interval inside the electronic device based on electromagnetic signal change data inside the electronic device when an operation disorder event occurs in the electronic device.

Alternatively, the acquiring operation state data of a motor driving device of an electric automobile under a driving condition, and estimating electromagnetic interference presence state information about each of all wiring harnesses connected to the motor driving device based on the operation state data; and identifying an abnormal wiring harness in which a signal conduction interference event occurs based on the electromagnetic interference presence state information includes:
acquiring reference operating current data of the motor driving device of the electric automobile under a reference driving condition, and analyzing the reference operating current data to obtain working current data of each of the all wiring harnesses connected to the motor driving device; and obtaining an effective working current data change model of the harness itself when a preset regular driving condition change of the electric automobile occurs based on the working current data;
acquiring actual operating current data of the motor driving device when the preset regular driving condition change of the electric automobile occurs, and analyzing the actual operating current data to obtain actual working current data of each of the all wiring harnesses; and comparing actual working current data of the wiring harness with predicted working current data estimated by a corresponding effective working current data change model, and determining electromagnetic interference intensity and frequency state information existing inside the wiring harness itself when the preset regular driving condition change occurs; and
obtaining an electromagnetic interference average intensity value and an electromagnetic interference peak frequency value inside the wiring harness itself based on the electromagnetic interference intensity and frequency state information, when the electromagnetic interference average intensity value is greater than a preset intensity threshold value or the electromagnetic interference peak frequency value is greater than a preset frequency threshold value, a corresponding wiring harness being determined as an abnormal wiring harness in which a signal conduction interference event occurs; otherwise, a corresponding wiring harness being not determined as an abnormal wiring harness in which a signal conduction interference event occurs.

Alternatively, when a corresponding wiring harness is not determined as an abnormal wiring harness in which a signal conduction interference event occurs, the following identification processing is performed for the corresponding wiring harness, including:
step S1, setting an actual working current value of the corresponding wiring harness as I, an actual working current frequency value as F, and a theoretical electromagnetic radiation intensity at a position with a distance D from the corresponding wiring harness as E:

$$E = \frac{1.3 {SIF}^{2}}{D} \qquad ( 1 )$$

where, S is a cross-sectional area formed by the corresponding wiring harness;
step S2, setting an electromagnetic radiation intensity actually measured at the position with the distance D from the corresponding wiring harness as E′, and a change ratio of the actually measured electromagnetic radiation intensity to the theoretical electromagnetic radiation intensity E as k:

$$k = \frac{{E}^{′}}{E} \qquad ( 2 )$$

step S3, calculating an electromagnetic radiation intensity E″ existing in the corresponding wiring harness itself when the preset regular driving condition change occurs,

$${E}^{″} = \frac{1.3 {SI}^{′} {F}^{′2} {F}^{{l}^{2}} {e}^{\frac{1}{k + 1}}}{D} \qquad ( 3 )$$

where, I′ is a working current value of the corresponding wiring harness itself when the preset regular driving condition change occurs, F′ is a working current frequency value of the corresponding wiring harness itself when the preset regular driving condition change occurs, and e is a natural constant; and
determining whether the electromagnetic radiation intensity E″ is within a preset electromagnetic radiation intensity range, if so, it being determined that the corresponding wiring harness is an abnormal harness in which no signal conduction interference event occurs; and if not, it being determined that the corresponding wiring harness is an abnormal harness in which a signal conduction interference event occurs.

Alternatively, the tracking and identifying an electromagnetic interference signal of the abnormal wiring harness to obtain propagation path information about the electromagnetic interference signal; and determining an electronic device which may be affected by the electromagnetic interference signal inside the electric automobile based on the propagation path information, and performing positioning identification on the electronic device includes:
performing signal sampling and identification on all signal transmission channels correspondingly connected to the abnormal wiring harness to obtain signal frequency domain information transmitted in real-time by the signal transmission channels; comparing the signal frequency domain information with frequency domain distribution feature information about an electromagnetic interference signal existing inside the abnormal wiring harness itself, if the signal frequency domain information matches the frequency domain distribution feature information, it being determined that the electromagnetic interference signal exists inside the signal transmission channel; and obtaining propagation path information about electromagnetic interference signals on the basis of all the signal transmission channels in which electromagnetic interference signals exist; and
determining all electronic devices capable of receiving the electromagnetic interference signal based on the propagation path information; and determining an intensity ratio of the electromagnetic interference signal in a real-time working current signal based on an actual working current signal of the electronic device, if the intensity ratio is greater than or equal to a preset ratio threshold value, it being determined that the electronic device may be affected by the electromagnetic interference signal, and it being determined that position information about the electronic device which may be affected by the electromagnetic interference signal in a global signal flow map of the electric automobile, as a result of the positioning identification.

Alternatively, the determining whether an operation disorder event occurs in the electronic device based on an operating record of the electronic device; and determining an electromagnetic interference concentrated circuit interval inside the electronic device based on electromagnetic signal change data inside the electronic device when an operation disorder event occurs in the electronic device includes:
acquiring an operating record of the electronic device which may be affected by the electromagnetic interference signal based on the result of the positioning identification, and analyzing the operating record to obtain a processing time consumption of a received signal by the electronic device, if the processing time consumption is greater than a preset time threshold value, it being determined that an operation disorder event occurs in the electronic device; otherwise, it being determined that no operation disorder event occurs in the electronic device; and
analyzing electromagnetic signal change data inside the electronic device when an operation disorder event occurs in the electronic device to obtain a high-frequency electromagnetic signal aggregate circuit part inside the electronic device, as an electromagnetic interference concentrated circuit interval inside the electronic device.

Compared with the prior art, the present disclosure has the following advantageous effects.

According to the electromagnetic interference testing system and method for an electric automobile under dynamic working conditions provided in the present application, based on the operation state data of the motor driving device of the electric automobile under a driving condition, the electromagnetic interference presence state information about each of all the wiring harnesses connected to the motor driving device is estimated to identify the abnormal wiring harness in which the signal conduction interference event occurs, which can accurately identify the propagation of electromagnetic interference inside the electric automobile; the electromagnetic interference signal of the abnormal wiring harness is tracked and identified to obtain the propagation path information about the electromagnetic interference signal, to determine the electronic device which may be affected by the electromagnetic interference signal inside the electric automobile, which is convenient for subsequent separate electromagnetic interference identification of the corresponding electronic device; and it is determined whether the operation disorder event occurs in the electronic device based on the operating record of the electronic device, and the electromagnetic interference concentrated circuit interval inside the electronic device is determined based on the electromagnetic signal change data inside the electronic device, which facilitates the subsequent electromagnetic interference shielding treatment for the corresponding circuit interval, improves the accuracy of battery interference identification of the electric automobile, and ensures the working reliability of the electric automobile.

### BRIEF DESCRIPTION OF THE DRAWINGS

To explain examples of the present disclosure or technical solutions in the prior art more clearly, a brief description will be given below with reference to accompanying drawings which are used in the description of the examples or the prior art. Obviously, the accompanying drawings in the description below are merely some examples of the present disclosure, and for those of ordinary skill in the art, other accompanying drawings can be obtained according to these accompanying drawings without creative efforts.

FIG. 1 is a schematic structural diagram of an electromagnetic interference testing system for an electric automobile under dynamic working conditions according to the present disclosure.

FIG. 2 is a schematic flow chart of an electromagnetic interference testing method for an electric automobile under dynamic working conditions according to the present disclosure.

### DETAILED DESCRIPTION

To make the above objects, features and advantages of the present application more apparent, a detailed description of specific implementations of the present application will be given below with reference to the accompanying drawings. It is to be understood that specific examples described herein are illustrative only and are not restrictive. It is to also be noted that, for ease of description, only some, but not all, of the structures associated with the present application are shown in the accompanying drawings. Based on the examples in the present application, all other examples obtained by those of ordinary skill in the art without creative efforts belong to the scope of protection of the present application.

The terms “include” and “have” as well as any variations thereof in the present application are intended to cover non-exclusive inclusion. For example, a process, method, system, product or device that includes a series of steps or units is not limited to the listed steps or units, but alternatively includes steps or units that are not listed, or alternatively includes other steps or units inherent to the process, method, product or device.

Reference herein to “example” means that a particular feature, structure, or characteristic described in connection with the example may be included in at least one example of the present application. The appearances of the phrase in various places in the specification are not necessarily all referring to the same example, nor are separate or alternative examples mutually exclusive of other examples. It is understood explicitly and implicitly by those skilled in the art that the examples described herein can be combined with other examples.

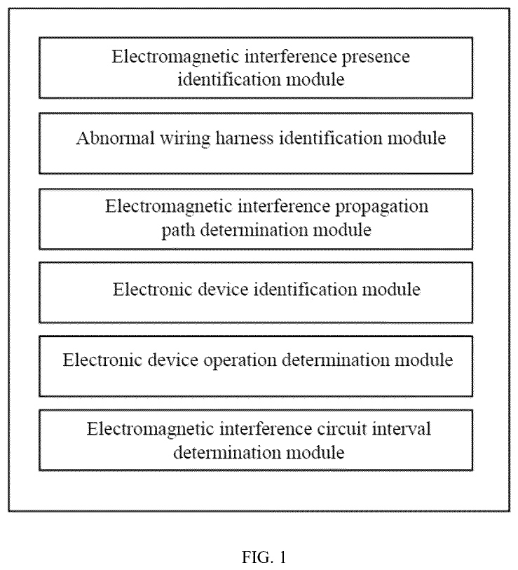

Referring to FIG. 1, an example of the present application provides an electromagnetic interference testing system for an electric automobile under dynamic working conditions, including:
an electromagnetic interference presence identification module, configured to acquire operation state data of a motor driving device of an electric automobile under a driving condition, and estimate electromagnetic interference presence state information about each of all wiring harnesses connected to the motor driving device based on the operation state data,
an abnormal wiring harness identification module, configured to identify an abnormal wiring harness in which a signal conduction interference event occurs based on the electromagnetic interference presence state information,
an electromagnetic interference propagation path determination module, configured to track and identify an electromagnetic interference signal of the abnormal wiring harness to obtain propagation path information about the electromagnetic interference signal,
an electronic device identification module, configured to determine an electronic device which may be affected by the electromagnetic interference signal inside the electric automobile based on the propagation path information, and perform positioning identification on the electronic device,
an electronic device operation determination module, configured to determine whether an operation disorder event occurs in the electronic device based on an operating record of the electronic device, and
an electromagnetic interference circuit interval determination module, configured to determine an electromagnetic interference concentrated circuit interval inside the electronic device based on electromagnetic signal change data inside the electronic device when an operation disorder event occurs in the electronic device.

The above example has the following advantageous effects. According to the electromagnetic interference testing system for an electric automobile under dynamic working conditions, based on operation state data of a motor driving device of an electric automobile under a driving condition, electromagnetic interference presence state information about each of all wiring harnesses connected to the motor driving device is estimated to identify an abnormal wiring harness in which a signal conduction interference event occurs, which can accurately identify the propagation of electromagnetic interference inside the electric automobile; an electromagnetic interference signal of the abnormal wiring harness is tracked and identified to obtain propagation path information about the electromagnetic interference signal, to determine an electronic device which may be affected by the electromagnetic interference signal inside the electric automobile, which is convenient for subsequent separate electromagnetic interference identification of a corresponding electronic device; and it is determined whether an operation disorder event occurs in the electronic device based on an operating record of the electronic device, and an electromagnetic interference concentrated circuit interval inside the electronic device is determined based on electromagnetic signal change data inside the electronic device, which facilitates the subsequent electromagnetic interference shielding treatment for a corresponding circuit interval, improves the accuracy of battery interference identification of the electric automobile, and ensures the working reliability of the electric automobile.

In another example, the electromagnetic interference presence identification module being configured to acquire operation state data of a motor driving device of an electric automobile under a driving condition, and estimate electromagnetic interference presence state information about each of all wiring harnesses connected to the motor driving device based on the operation state data includes that:
reference operating current data of the motor driving device of the electric automobile is acquired under a reference driving condition, and the reference operating current data is analyzed to obtain working current data of each of the all wiring harnesses connected to the motor driving device; and an effective working current data change model of the harness itself is obtained when a preset regular driving condition change of the electric automobile occurs based on the working current data; and
actual operating current data of the motor driving device is acquired when the preset regular driving condition change of the electric automobile occurs, and the actual operating current data is analyzed to obtain actual working current data of each of the all wiring harnesses; and actual working current data of the wiring harness is compared with predicted working current data estimated by a corresponding effective working current data change model, and electromagnetic interference intensity and frequency state information existing inside the wiring harness itself are determined when the preset regular driving condition change occurs.

The abnormal wiring harness identification module being configured to identify an abnormal wiring harness in which a signal conduction interference event occurs based on the electromagnetic interference presence state information includes that:
an electromagnetic interference average intensity value and an electromagnetic interference peak frequency value inside the wiring harness itself are obtained based on the electromagnetic interference intensity and frequency state information, when the electromagnetic interference average intensity value is greater than a preset intensity threshold value or the electromagnetic interference peak frequency value is greater than a preset frequency threshold value, a corresponding wiring harness being determined as an abnormal wiring harness in which a signal conduction interference event occurs; otherwise, a corresponding wiring harness being not determined as an abnormal wiring harness in which a signal conduction interference event occurs.

The above example has the following advantageous effects. The motor driving device serves as a main source of high-frequency electromagnetic interference signals inside the electric automobile, and when the motor driving device performs high-speed operation, the high-frequency electromagnetic interference signals will be transmitted to the outside, but the motor driving device will not transmit the high-frequency electromagnetic interference signals to the outside under any operation conditions. For example, when the motor driving device is in a low-speed operation state, the high-frequency electromagnetic interference signals will not be generated, and at this time, reference operating current data of the motor driving device of the electric automobile under a reference driving condition (for example, a preset low-speed range driving condition) is acquired. By analyzing the reference operating current data, the corresponding working current data of each of all the wiring harnesses connected to the motor driving device in a current operating state of the motor driving device can be obtained, so that the basic characterization of the working current data of all the wiring harnesses can be carried out. Taking the working current data as a reference, an effective working current data change model of the wiring harness itself is obtained when the preset regular driving condition change of the electric automobile occurs. The effective working current data change model can take the working current data as a reference, predicting a working current correspondingly transmitted to all the wiring harnesses when the motor driving device is loaded with different working conditions due to the preset regular driving condition change of the electric automobile, to characterize ideal working current data corresponding to all the wiring harnesses which are not affected by the high-frequency electromagnetic interference signal. The actual operating current data of the motor driving device is acquired when the preset regular driving condition change of the electric automobile occurs, and the actual operating current data is analyzed to obtain the actual working current data of each of all the wiring harnesses; and the actual working current data of the wiring harness is compared with the predicted working current data estimated by the corresponding effective working current data change model, the electromagnetic interference intensity and frequency state information existing inside the wiring harness itself are determined when the preset regular driving condition change occurs, and the high-frequency electromagnetic interference generated by the motor driving device is accurately analyzed. Based on the electromagnetic interference intensity and frequency state information, the electromagnetic interference average intensity value and the electromagnetic interference peak frequency value within the wiring harness itself are obtained, and the threshold value comparison is performed on the electromagnetic interference average intensity value and the electromagnetic interference peak frequency value, to accurately identify the abnormal wiring harness in which the signal conduction interference event occurs.

In another example, the electromagnetic interference propagation path determination module being configured to track and identify an electromagnetic interference signal of the abnormal wiring harness to obtain propagation path information about the electromagnetic interference signal includes that:
signal sampling and identification are performed on all signal transmission channels correspondingly connected to the abnormal wiring harness to obtain signal frequency domain information transmitted in real-time by the signal transmission channels; the signal frequency domain information is compared with frequency domain distribution feature information about an electromagnetic interference signal existing inside the abnormal wiring harness itself, if the signal frequency domain information matches the frequency domain distribution feature information, it being determined that the electromagnetic interference signal exists inside the signal transmission channel; and propagation path information about electromagnetic interference signals is obtained on the basis of all the signal transmission channels in which electromagnetic interference signals exist.

The electronic device identification module being configured to determine an electronic device which may be affected by the electromagnetic interference signal inside the electric automobile based on the propagation path information, and perform positioning identification on the electronic device includes that:
all electronic devices capable of receiving the electromagnetic interference signal are determined based on the propagation path information; an intensity ratio of the electromagnetic interference signal in a real-time working current signal is determined based on an actual working current signal of the electronic device, if the intensity ratio is greater than or equal to a preset ratio threshold value, it being determined that the electronic device may be affected by the electromagnetic interference signal, and it being determined that position information about the electronic device which may be affected by the electromagnetic interference signal in a global signal flow map of the electric automobile, as a result of the positioning identification.

The above example has the following advantageous effects. The signal sampling and identification are performed on all signal transmission channels correspondingly connected to the abnormal wiring harness to obtain signal frequency domain information transmitted in real-time by the signal transmission channels; and the signal frequency domain information is compared with frequency domain distribution feature information about an electromagnetic interference signal existing inside the abnormal wiring harness itself. If the signal frequency domain information matches the frequency domain distribution feature information, it is determined that the electromagnetic interference signal exists inside the signal transmission channel, otherwise, it is determined that the electromagnetic interference signal does not exist inside the signal transmission channel, so that the distribution of the electromagnetic interference signals in all the signal transmission channels can be accurately identified. Propagation path information about electromagnetic interference signals is obtained on the basis of all the signal transmission channels in which electromagnetic interference signals exist, and a transmission trend state of the electromagnetic interference signal in the electric automobile is determined comprehensively. In addition, all electronic devices capable of receiving the electromagnetic interference signal are determined based on the propagation path information; and an intensity ratio of the electromagnetic interference signal in a real-time working current signal is determined based on an actual working current signal of the electronic device, and the intensity ratio is compared with a threshold value to determine whether the electronic device may be affected by the electromagnetic interference signal, to facilitate the subsequent individual depth identification only for the electronic device affected by the electromagnetic interference signal.

In another example, the electronic device operation determination module being configured to determine whether an operation disorder event occurs in the electronic device based on an operating record of the electronic device includes that:
an operating record of the electronic device which may be affected by the electromagnetic interference signal is acquired based on the result of the positioning identification, and the operating record is analyzed to obtain a processing time consumption of a received signal by the electronic device, if the processing time consumption is greater than a preset time threshold value, it being determined that an operation disorder event occurs in the electronic device; otherwise, it being determined that no operation disorder event occurs in the electronic device; and
the electromagnetic interference circuit interval determination module being configured to determine an electromagnetic interference concentrated circuit interval inside the electronic device based on electromagnetic signal change data inside the electronic device when an operation disorder event occurs in the electronic device includes that:
electromagnetic signal change data inside the electronic device is analyzed when an operation disorder event occurs in the electronic device to obtain a high-frequency electromagnetic signal aggregate circuit part inside the electronic device, as an electromagnetic interference concentrated circuit interval inside the electronic device.

The above example has the following advantageous effects. The operating record of the electronic device which may be affected by the electromagnetic interference signal is acquired based on the result of the positioning identification, the operating record is analyzed to obtain a processing time consumption of a received signal by the electronic device, the processing time consumption is compared with a threshold value, and it is accurately determined that whether an operation disorder event occurs in the electronic device. In addition, electromagnetic signal change data inside the electronic device is analyzed when an operation disorder event occurs in the electronic device to obtain a high-frequency electromagnetic signal aggregate circuit part inside the electronic device, as an electromagnetic interference concentrated circuit interval inside the electronic device, to facilitate the subsequent special interference shielding or filtering processing for the electromagnetic interference concentrated circuit interval.

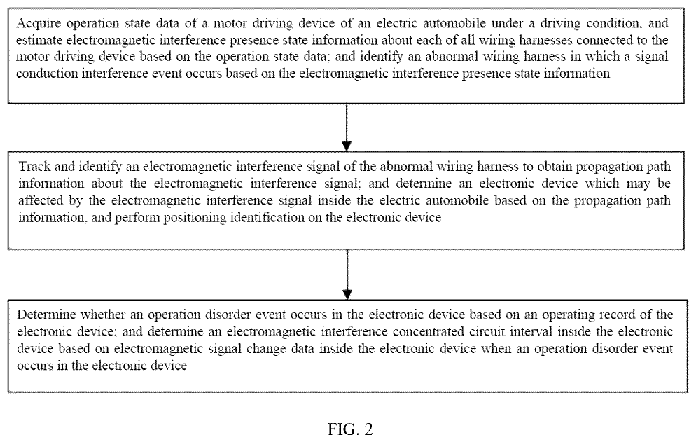

Referring to FIG. 2, an example of the present application provides an electromagnetic interference testing method for an electric automobile under dynamic working conditions, including that:
operation state data of a motor driving device of an electric automobile is acquired under a driving condition, and electromagnetic interference presence state information about each of all wiring harnesses connected to the motor driving device is estimated based on the operation state data; and an abnormal wiring harness in which a signal conduction interference event occurs is identified based on the electromagnetic interference presence state information;
an electromagnetic interference signal of the abnormal wiring harness is tracked and identified to obtain propagation path information about the electromagnetic interference signal; and an electronic device which may be affected by the electromagnetic interference signal inside the electric automobile is determined based on the propagation path information, and positioning identification is performed on the electronic device; and
it is determined whether an operation disorder event occurs in the electronic device based on an operating record of the electronic device; and an electromagnetic interference concentrated circuit interval inside the electronic device is determined based on electromagnetic signal change data inside the electronic device when an operation disorder event occurs in the electronic device.

The above example has the following advantageous effects. According to the electromagnetic interference testing method for an electric automobile under dynamic working conditions, based on the operation state data of the motor driving device of the electric automobile under a driving condition, the electromagnetic interference presence state information about each of all the wiring harnesses connected to the motor driving device is estimated to identify the abnormal wiring harness in which the signal conduction interference event occurs, which can accurately identify the propagation of electromagnetic interference inside the electric automobile; the electromagnetic interference signal of the abnormal wiring harness is tracked and identified to obtain propagation path information about the electromagnetic interference signal, to determine the electronic device which may be affected by the electromagnetic interference signal inside the electric automobile, which is convenient for subsequent separate electromagnetic interference identification of the corresponding electronic device; and it is determined whether an operation disorder event occurs in the electronic device based on the operating record of the electronic device, and the electromagnetic interference concentrated circuit interval inside the electronic device is determined based on the electromagnetic signal change data inside the electronic device, which facilitates the subsequent electromagnetic interference shielding treatment for the corresponding circuit interval, improves the accuracy of battery interference identification of the electric automobile, and ensures the working reliability of the electric automobile.

In another example, the operation state data of a motor driving device of an electric automobile being acquired under a driving condition, and electromagnetic interference presence state information about each of all wiring harnesses connected to the motor driving device being estimated based on the operation state data; and an abnormal wiring harness in which a signal conduction interference event occurs being identified based on the electromagnetic interference presence state information includes that:
reference operating current data of the motor driving device of the electric automobile is acquired under a reference driving condition, and the reference operating current data is analyzed to obtain working current data of each of the all wiring harnesses connected to the motor driving device; and an effective working current data change model of the harness itself is obtained when a preset regular driving condition change of the electric automobile occurs based on the working current data;
actual operating current data of the motor driving device is acquired when the preset regular driving condition change of the electric automobile occurs, and the actual operating current data is analyzed to obtain actual working current data of each of the all wiring harnesses; and actual working current data of the wiring harness is compared with predicted working current data estimated by a corresponding effective working current data change model, and electromagnetic interference intensity and frequency state information existing inside the wiring harness itself are determined when the preset regular driving condition change occurs; and
an electromagnetic interference average intensity value and an electromagnetic interference peak frequency value inside the wiring harness itself are obtained based on the electromagnetic interference intensity and frequency state information, when the electromagnetic interference average intensity value is greater than a preset intensity threshold value or the electromagnetic interference peak frequency value is greater than a preset frequency threshold value, a corresponding wiring harness being determined as an abnormal wiring harness in which a signal conduction interference event occurs; otherwise, a corresponding wiring harness being not determined as an abnormal wiring harness in which a signal conduction interference event occurs.

The above example has the following advantageous effects. The motor driving device serves as a main source of high-frequency electromagnetic interference signals inside the electric automobile, and when the motor driving device performs high-speed operation, the high-frequency electromagnetic interference signals will be transmitted to the outside, but the motor driving device will not transmit the high-frequency electromagnetic interference signals to the outside under any operation conditions. For example, when the motor driving device is in a low-speed operation state, the high-frequency electromagnetic interference signals will not be generated, and at this time, reference operating current data of the motor driving device of the electric automobile under a reference driving condition (for example, a preset low-speed range driving condition) is acquired. By analyzing the reference operating current data, the corresponding working current data of each of all the wiring harnesses connected to the motor driving device in a current operating state of the motor driving device can be obtained, so that the basic characterization of the working current data of all the wiring harnesses can be carried out. Taking the working current data as a reference, an effective working current data change model of the wiring harness itself is obtained when the preset regular driving condition change of the electric automobile occurs. The effective working current data change model can take the working current data as a reference, predicting a working current correspondingly transmitted to all the wiring harnesses when the motor driving device is loaded with different working conditions due to the preset regular driving condition change of the electric automobile, to characterize ideal working current data corresponding to all the wiring harnesses which are not affected by the high-frequency electromagnetic interference signal. The actual operating current data of the motor driving device is acquired when the preset regular driving condition change of the electric automobile occurs, and the actual operating current data is analyzed to obtain the actual working current data of each of all the wiring harnesses; and the actual working current data of the wiring harness is compared with the predicted working current data estimated by the corresponding effective working current data change model, the electromagnetic interference intensity and frequency state information existing inside the wiring harness itself are determined when the preset regular driving condition change occurs, and the high-frequency electromagnetic interference generated by the motor driving device is accurately analyzed. Based on the electromagnetic interference intensity and frequency state information, the electromagnetic interference average intensity value and the electromagnetic interference peak frequency value within the wiring harness itself are obtained, and the threshold value comparison is performed on the electromagnetic interference average intensity value and the electromagnetic interference peak frequency value, to accurately identify the abnormal wiring harness in which the signal conduction interference event occurs.

In another example, the electromagnetic interference intensity and frequency state information existing in the wiring harness itself when the preset regular driving condition change occurs are complex and variable, for example, the wiring harness may be affected by the transient voltage magnitude, electrostatic discharge, wiring harness coupling and other factors, so that under the influence of different factors, the difficulty of accurately measuring the electromagnetic interference intensity inside the wiring harness itself is increased, the accuracy rate of identifying the abnormal wiring harness may be reduced, and the abnormal wiring harness may not be accurately identified. If the identification is incorrect, the subsequent processing for the identified abnormal wiring harness is invalid and negative; and if the identification is omitted, an unidentified abnormal wiring harness will pose a potential threat to the safety of the electric automobile and may cause a major safety accident. In order to exclude the influence of external factors on the identification of abnormal wiring harnesses, when a corresponding wiring harness is not determined as an abnormal wiring harness in which a signal conduction interference event occurs, the following identification processing is performed for the corresponding wiring harness, including the following steps.

In step S1, an actual working current value of the corresponding wiring harness is set as I, an actual working current frequency value is set as F, and a theoretical electromagnetic radiation intensity at a position with a distance D from the corresponding wiring harness is set as E.

$$E = \frac{1.3 {SIF}^{2}}{D} \qquad ( 1 )$$

where, S is a cross-sectional area formed by the corresponding wiring harness.

In step S2, there are other power-on devices in a power-on process of the wiring harness, such as wiper driving motor, automobile start motor, heater motor, etc., as well as other power-on wiring harness coupling and environmental static electricity, an electromagnetic radiation intensity actually measured at the position with the distance D from the corresponding wiring harness is set as E′, and a change ratio of the actually measured electromagnetic radiation intensity to the theoretical electromagnetic radiation intensity E is set as k.

$$k = \frac{{E}^{′}}{E} . \qquad ( 2 )$$

In step S3, an electromagnetic radiation intensity E″ existing in the corresponding wiring harness itself is calculated when the preset regular driving condition change occurs,

$${E}^{″} = \frac{1.3 {SI}^{′} {F}^{′2} {F}^{{l}^{2}} {e}^{\frac{1}{k + 1}}}{D} \qquad ( 3 )$$

where, I′ is a working current value of the corresponding wiring harness itself when the preset regular driving condition change occurs, F′ is a working current frequency value of the corresponding wiring harness itself when the preset regular driving condition change occurs, and e is a natural constant.

Finally, it is determined whether the electromagnetic radiation intensity E″ is within a preset electromagnetic radiation intensity range, if so, it being determined that the corresponding wiring harness is an abnormal harness in which no signal conduction interference event occurs; and if not, it being determined that the corresponding wiring harness is an abnormal harness in which a signal conduction interference event occurs.

The above example has the following advantageous effects. According to numerical values of a theoretical electromagnetic radiation intensity and an actual electromagnetic radiation intensity of a target wiring harness at a given distance, the electromagnetic radiation intensity of the target wiring harness affected by environmental factors at the given distance is determined, and the electromagnetic radiation intensity existing inside the target wiring harness itself is further determined when a preset regular driving condition change occurs, to determine whether the target wiring harness is an abnormal wiring harness, increasing the accuracy rate of identification of the abnormal wiring harness, avoiding unnecessary investment and loss due to identification errors, ensuring the safety of the electric automobile to a certain extent and avoiding the occurrence of a safety accident.

In another example, the electromagnetic interference signal of the abnormal wiring harness being tracked and identified to obtain propagation path information about the electromagnetic interference signal; and an electronic device which may be affected by the electromagnetic interference signal inside the electric automobile being determined based on the propagation path information, and positioning identification being performed on the electronic device includes that:
signal sampling and identification are performed on all signal transmission channels correspondingly connected to the abnormal wiring harness to obtain signal frequency domain information transmitted in real-time by the signal transmission channels; the signal frequency domain information is compared with frequency domain distribution feature information about an electromagnetic interference signal existing inside the abnormal wiring harness itself, if the signal frequency domain information matches the frequency domain distribution feature information, it being determined that the electromagnetic interference signal exists inside the signal transmission channel; and propagation path information about electromagnetic interference signals is obtained on the basis of all the signal transmission channels in which electromagnetic interference signals exist; and
all electronic devices capable of receiving the electromagnetic interference signal are determined based on the propagation path information; an intensity ratio of the electromagnetic interference signal in a real-time working current signal is determined based on an actual working current signal of the electronic device, if the intensity ratio is greater than or equal to a preset ratio threshold value, it being determined that the electronic device may be affected by the electromagnetic interference signal, and it being determined that position information about the electronic device which may be affected by the electromagnetic interference signal in a global signal flow map of the electric automobile, as a result of the positioning identification.

The above example has the following advantageous effects. The signal sampling and identification are performed on all signal transmission channels correspondingly connected to the abnormal wiring harness to obtain signal frequency domain information transmitted in real-time by the signal transmission channels; and the signal frequency domain information is compared with frequency domain distribution feature information about an electromagnetic interference signal existing inside the abnormal wiring harness itself. If the signal frequency domain information matches the frequency domain distribution feature information, it is determined that the electromagnetic interference signal exists inside the signal transmission channel, otherwise, it is determined that the electromagnetic interference signal does not exist inside the signal transmission channel, so that the distribution of the electromagnetic interference signals in all the signal transmission channels can be accurately identified. Propagation path information about electromagnetic interference signals is obtained on the basis of all the signal transmission channels in which electromagnetic interference signals exist, and a transmission trend state of the electromagnetic interference signal in the electric automobile is determined comprehensively. In addition, all electronic devices capable of receiving the electromagnetic interference signal are determined based on the propagation path information; and an intensity ratio of the electromagnetic interference signal in a real-time working current signal is determined based on an actual working current signal of the electronic device, and the intensity ratio is compared with a threshold value to determine whether the electronic device may be affected by the electromagnetic interference signal, to facilitate the subsequent individual depth identification only for the electronic device affected by the electromagnetic interference signal.

In another example, the it being determined whether an operation disorder event occurs in the electronic device based on an operating record of the electronic device; and an electromagnetic interference concentrated circuit interval inside the electronic device being determined based on electromagnetic signal change data inside the electronic device when an operation disorder event occurs in the electronic device includes that:
an operating record of the electronic device which may be affected by the electromagnetic interference signal is acquired based on the result of the positioning identification, and the operating record is analyzed to obtain a processing time consumption of a received signal by the electronic device, if the processing time consumption is greater than a preset time threshold value, it being determined that an operation disorder event occurs in the electronic device; otherwise, it being determined that no operation disorder event occurs in the electronic device; and
electromagnetic signal change data inside the electronic device is analyzed when an operation disorder event occurs in the electronic device to obtain a high-frequency electromagnetic signal aggregate circuit part inside the electronic device, as an electromagnetic interference concentrated circuit interval inside the electronic device.

The above example has the following advantageous effects. The operating record of the electronic device which may be affected by the electromagnetic interference signal is acquired based on the result of the positioning identification, the operating record is analyzed to obtain a processing time consumption of a received signal by the electronic device, the processing time consumption is compared with a threshold value, and it is accurately determined that whether an operation disorder event occurs in the electronic device. In addition, electromagnetic signal change data inside the electronic device is analyzed when an operation disorder event occurs in the electronic device to obtain a high-frequency electromagnetic signal aggregate circuit part inside the electronic device, as an electromagnetic interference concentrated circuit interval inside the electronic device, to facilitate the subsequent special interference shielding or filtering processing for the electromagnetic interference concentrated circuit interval.

In general, according to the electromagnetic interference testing system and method for an electric automobile under dynamic working conditions, based on the operation state data of the motor driving device of the electric automobile under a driving condition, the electromagnetic interference presence state information about each of all the wiring harnesses connected to the motor driving device is estimated to identify the abnormal wiring harness in which the signal conduction interference event occurs, which can accurately identify the propagation of electromagnetic interference inside the electric automobile; the electromagnetic interference signal of the abnormal wiring harness is tracked and identified to obtain the propagation path information about the electromagnetic interference signal, to determine the electronic device which may be affected by the electromagnetic interference signal inside the electric automobile, which is convenient for subsequent separate electromagnetic interference identification of a corresponding electronic device; and it is determined whether the operation disorder event occurs in the electronic device based on the operating record of the electronic device, and the electromagnetic interference concentrated circuit interval inside the electronic device is determined based on the electromagnetic signal change data inside the electronic device, which facilitates the subsequent electromagnetic interference shielding treatment for the corresponding circuit interval, improves the accuracy of battery interference identification of the electric automobile, and ensures the working reliability of the electric automobile.

The above is only a specific implementation of the present disclosure, and any other improvements based on the concept of the present disclosure are regarded as the scope of protection of the present disclosure.

1. (canceled)

2. (canceled)

3. (canceled)

4. A computer-implemented electromagnetic interference testing method for an electric automobile under dynamic working conditions, comprising:
acquiring operation state data of a motor driving device of an electric automobile under a driving condition,
tracking and identifying an electromagnetic interference signal of an abnormal wiring harness in which a signal conduction interference event occurs to obtain propagation path information about the electromagnetic interference signal, wherein the abnormal wiring harness is identified based on electromagnetic interference presence state information about each of all wiring harnesses connected to the motor driving device, and the electromagnetic interference presence state information is estimated based on the operation state data; and performing positioning identification on an electronic device which is determined to be affected by the electromagnetic interference signal inside the electric automobile based on the propagation path information, and
determining whether an operation disorder event occurs in the electronic device based on an operating record of the electronic device, wherein
the acquiring operation state data of a motor driving device of an electric automobile under a driving condition comprises:
acquiring reference operating current data of the motor driving device of the electric automobile under a reference driving condition, and analyzing the reference operating current data to obtain working current data of each of the all wiring harnesses connected to the motor driving device; and obtaining an effective working current data change model of the harness itself when a preset regular driving condition change of the electric automobile occurs based on the working current data; and
acquiring actual operating current data of the motor driving device when the preset regular driving condition change of the electric automobile occurs, and analyzing the actual operating current data to obtain actual working current data of each of the all wiring harnesses; and comparing actual working current data of the wiring harness with predicted working current data estimated by a corresponding effective working current data change model, and determining electromagnetic interference intensity and frequency state information existing inside the wiring harness itself when the preset regular driving condition change occurs; and
obtaining an electromagnetic interference average intensity value and an electromagnetic interference peak frequency value inside the wiring harness itself based on the electromagnetic interference intensity and frequency state information, when the electromagnetic interference average intensity value is greater than a preset intensity threshold value or the electromagnetic interference peak frequency value is greater than a preset frequency threshold value, a corresponding wiring harness being determined as the abnormal wiring harness in which the signal conduction interference event occurs; otherwise, a corresponding wiring harness being not determined as the abnormal wiring harness in which the signal conduction interference event occurs;
when a corresponding wiring harness is not determined as the abnormal wiring harness in which the signal conduction interference event occurs, calculating an electromagnetic radiation intensity existing in the corresponding wiring harness itself when the preset regular driving condition change occurs by following formulas:
$$E = \frac{1.3 {SIF}^{2}}{D} \qquad ( 1 )$$
where, S is a cross-sectional area formed by the corresponding wiring harness, I is an actual working current value of the corresponding wiring harness, F is an actual working current frequency value, D is a distance, and E is a theoretical electromagnetic radiation intensity at a position with the distance D from the corresponding wiring harness;
$$k = \frac{{E}^{′}}{E} \qquad ( 2 )$$
where, E′ is an electromagnetic radiation intensity actually measured at the position with the distance D from the corresponding wiring harness, and k is a ratio of the actually measured electromagnetic radiation intensity E′ to the theoretical electromagnetic radiation intensity E;
$${E}^{″} = \frac{1.3 {SI}^{′} {F}^{′2} {F}^{{l}^{2}} {e}^{\frac{1}{k + 1}}}{D} \qquad ( 3 )$$
where, I′ is a working current value of the corresponding wiring harness itself when the preset regular driving condition change occurs, F′ is a working current frequency value of the corresponding wiring harness itself when the preset regular driving condition change occurs, e is a natural constant, and E″ is an electromagnetic radiation intensity existing in the corresponding wiring harness itself when the preset regular driving condition change occurs; and
performing identification on the corresponding wiring harness based on the electromagnetic radiation intensity E″;
wherein performing identification on the corresponding wiring harness based on the electromagnetic radiation intensity E″, comprises: determining whether the electromagnetic radiation intensity E″ is within a preset electromagnetic radiation intensity range; if so, determining that the corresponding wiring harness is an abnormal harness in which no signal conduction interference event occurs; and if not, determining that the corresponding wiring harness is an abnormal harness in which the signal conduction interference event occurs;
wherein the tracking and identifying an electromagnetic interference signal of the abnormal wiring harness in which a signal conduction interference event occurs to obtain propagation path information about the electromagnetic interference signal comprises:
performing signal sampling and identification on all signal transmission channels correspondingly connected to the abnormal wiring harness to obtain signal frequency domain information transmitted in real-time by the signal transmission channels; comparing the signal frequency domain information with frequency domain distribution feature information about an electromagnetic interference signal existing inside the abnormal wiring harness itself, if the signal frequency domain information matches the frequency domain distribution feature information, determining that the electromagnetic interference signal exists inside the signal transmission channel; and obtaining propagation path information about electromagnetic interference signals on the basis of all the signal transmission channels in which electromagnetic interference signals exist;
wherein the performing positioning identification on the electronic device which is determined to be affected by the electromagnetic interference signal inside the electric automobile based on the propagation path information comprises:
determining all electronic devices capable of receiving the electromagnetic interference signal based on the propagation path information; and determining an intensity ratio of the electromagnetic interference signal in a actual working current signal based on the actual working current signal of the electronic device; if the intensity ratio is greater than or equal to a preset ratio threshold value, determining that the electronic device is affected by the electromagnetic interference signal; and determining that position information about the electronic device which is affected by the electromagnetic interference signal in a global signal flow map of the electric automobile, as a result of the positioning identification;
wherein the determining whether an operation disorder event occurs in the electronic device based on an operating record of the electronic device comprises:
acquiring an operating record of the electronic device which is affected by the electromagnetic interference signal based on the result of the positioning identification; and analyzing the operating record to obtain a processing time consumption of a received signal by the electronic device; if the processing time consumption is greater than a preset time threshold value, determining that an operation disorder event occurs in the electronic device; otherwise, determining that no operation disorder event occurs in the electronic device.

5. (canceled)

6. (canceled)
